(19) United States
(12) Patent Application Publication
(10) Pub. No.: US 2004/0227226 A1
(43) Pub. Date: Nov. 18, 2004

(54) Structure of multi-tier wire bonding for high frequency integrated circuits and method of layout for the same

(75) Inventor: Jimmy Hsu, Taipei (TW)

Correspondence Address: BRUCE H. TROXELL, SUITE 1404, 5205 LEESBURG PIKE, FALLS CHURCH, VA, 22041, US

(73) Assignee: VIA TECHNOLOGIES, INC.

(21) Appl. No.: 10/778,143

(22) Filed: Feb. 17, 2004

(30) Foreign Application Priority Data
May 16, 2003 (TW) 92113276

(51) Int. Cl. B65B 13/02; H01L 21/44

(52) U.S. Cl. 257/691; 257/692; 257/784; 438/617; 257/786; 438/612

(57) ABSTRACT

The present invention is to provide a structure of multi-tier wire bonding for high frequency integrated circuits. The structure comprises a first electronic device, a second electronic device and a plurality of metal wires. The first electronic device has a first bonding surface, a first carrying surface and a first grouping of bonding pads. The first grouping of bonding pads is distributed surrounding the border of the first bonding surface, and the first grouping of bonding pads at least can be divided into the first row and the second row bonding pads. The second electronic device has the second carrying surface and a plurality of second grouping of bonding pads. The second carrying surface is abutted against the first carrying surface for carrying the first electronic device, such that the first electronic device and the second electronic device overlap one another. Moreover, the method comprises: using reverse bonding to bond a metal wire starting from one bonding pad of the second grouping of bonding pads and ending at one bonding pad of the first row bonding pads; moreover, using normal bonding to bond a metal wire starting from one bonding pad of the first grouping of bonding pads and ending at one bonding pad of the second grouping of bonding pads.

### FIELD OF THE INVENTION

The present invention relates to a structure of multi-tier wire bonding for high frequency integrated circuits and a method of layout for the same, and more particularly, to a structure of multi-tier wire bonding for high frequency integrated circuits and a method of layout for the same capable of using both normal bonding and reverse bonding simultaneously for enabling the electrical connection between the chip and the package to have best electrical characteristics.

### DESCRIPTION OF THE PRIOR ARTS

The purpose of electronic package is to provide a structural framework and a protective enclosure for circuits that enables the transfer of signals amongst electronic devices and between electronic hardware and humans, and also provides a means for heat dissipation. The term “electronic packaging” encompasses the materials and interconnections, as well as the production and assembly processes, needed to create electronic products. Thus, in order to catch up with the increasing demand for electronic products with high operating frequency and high operating efficiency, the improvement of package design is critical factor for enhancing the performance of electronic products.

Please refer to the FIG. 1, which is a top view showing a package structure of prior art. The conventional package structure 100 contains a chip 105 and a substrate 110 having internal circuits therein. The electrical connection between the chip 100 and the substrate 110 is accomplished by using the metal wires 140 to connect the bonding pads 130 of the chip 100 and the pads 120 of the substrate 110. Moreover, the electrical connection between the chip 105 and the printed circuit board (PCB) containing electronic parts (not shown) is accomplished through the leads.

Please refer to the FIG. 2A, which is a sectional view of a conventional lead frame package structure. The package structure 200 mainly comprises a substrate 210 and a chip 240, wherein a die pad 220 covered with a layer of epoxy 225 is arranged on the substrate 210 for supporting the chip 240. The electrical connection between the chip 240 and the substrate 210 is achieved by using the metal wires 242, 243 to connect respectively the bonding pads 245, 243 on the bonding surface 241 of the chip 240 and the pads 237, 239 of the lead 230, 235 of the substrate 210.

However, because the RF (Radio Frequency) circuit or high-speed circuit demands high operating frequency and efficiency, the number of the bonding wire in the conventional package structure is prone to increase, and consequently the amount of rows of the bonding pads arranged on the bonding surface 241 of the chip 240 is increased accordingly, and further the area of the die pad covered by the layer of epoxy 225 is smaller for improving the electrical characteristics of the package structure 200.

Please refer to FIG. 2B, which is a sectional view of a conventional package structure. The bonding pads 248, 249 are added respectively at the sides of bonding pads 245, 247. The area of the die pad covered by the layer of epoxy 225 is smaller than that in FIG. 2A. In this regard, the area of the die pad 220 not covered by the layer of epoxy 225 can be employed as a grounding surface since the die pad 220 is an insulator, such that the bonding pad 245, 247 can be grounded directly through the metal wires 260, 270 and the area of the die pad 220 not covered by the epoxy 225 without the use of the pads 237, 239. Thus, the grounding in the FIG. 2B is shorter than that in FIG. 2A since the metal wires 260, 270 are much shorter than the metal wires 242, 243. Therefore, the grounding of the chip 240 can be achieved using shorter metal wires 260, 270 such that the electrical characteristics and the heat dissipation capability are improved.

However, In the RF circuit or high-speed circuit, although a plurality of grounding points are provided to connect the chip with the substrate using shorter metal wires, the high frequency signal will suffer a large distortion due to the limitations of bonding pad location and the arcs for bonding the metal wires. In addition, for the package structure covered with a molding compound, such as QFN, BCC++, or CSP, which has a lower molding height that further increases the limitation set on the arcs and the difficulty of bonding the metal wire, the tri-tier formation of bonding pad for wire bonding is almost impossible to be performed on the foregoing package structure.

Thus, the present invention provides a structure of multi-tier wire bonding for high frequency integrated circuits capable of reducing the insertion loss and increasing the return loss so as to enhance the overall electrical characteristics of the package structure.

### SUMMARY OF THE INVENTION

The primary object of the present invention is to provide a structure of multi-tier wire bonding for high frequency integrated circuits. The structure comprises a first electronic device, a second electronic device and, a plurality of metal wires. The first electronic device has a first bonding surface, a first carrying surface and a first grouping of bonding pads. The first carrying surface locates at a side of the first electronic device, which is opposite to the first bonding surface. The first grouping of bonding pads is distributed surrounding the border of the first bonding surface. Moreover, the first grouping of bonding pads at least can be divided into the first row and the second row bonding pads, that the first row of bonding pads is away from whereas the second row bonding pads are close to the center of the first bonding surface. The second electronic device has the second carrying surface and a plurality of second grouping of bonding pads. The second carrying surface is abutted against the first carrying surface for carrying the first electronic device, such that the first electronic device and the second electronic device overlap one another. The second grouping of bonding pads located on the second carrying surface is distributed surrounding the border thereof. The electrical connection between the first electronic device and the second electronic device is accomplished by using the metal wires to connect the first electronic device and the second electronic device. Some of the metal wires employ method of normal bonding for bonding whereas the others employ reverse bonding. Both the wire of normal bonding and the wire of reverse bonding have respectively an initial point and a cutting point. Wherein, the initial point of a wire of normal bonding is connected to a bonding pad of the first grouping, and the cutting point of a wire of normal bonding is connected to a bonding pad of the second grouping. On the other hand, the connection for the wires of reverse bonding is the opposite to that of the wires of normal bonding.

Another object of the present invention is to provide a method of layout for the aforementioned structure, comprising: using the method of reverse bonding to bond a metal wire starting from one bonding pad of the second grouping of bonding pads and ending at one bonding pad of the first row bonding pads; moreover, using the method of normal bonding to bond a metal wire starting from one bonding pad of the first grouping of bonding pads and ending at one bonding pad of the second grouping of bonding pads.

In summary, the present invention provides a structure of multi-tier wire bonding for high frequency integrated circuits and a method of layout for the same capable of using both normal bonding and reverse bonding simultaneously for enabling the electrical connection between the first electronic device and the second electronic device, such that multi-tier bonding can be achieved and also both the reflection induced by the mismatch and the insertion loss are reduced so as to have a better electrical characteristics.

### BRIEF DESCRIPTION OF THE DRAWINGS

FIG. 1 is a top view of a conventional package structure.

FIG. 2A is a sectional view of a conventional package structure.

FIG. 2B is a sectional view of another conventional package structure.

FIG. 3 is a 3D schematic drawing showing a conventional package structure with normal bonding layout.

FIG. 4 is a 3D schematic drawing showing a conventional package structure with reverse bonding layout.

FIG. 5 is a schematic drawing showing an embodiment of a package structure with multiple rows of bonding pads.

FIG. 6A is a schematic drawing showing a grouping of bonding pads with two rows of interlace-arranged bonding pads.

FIG. 6B is a schematic drawing showing a grouping of bonding pads with three rows of interlace-arranged bonding pads.

FIG. 7A is a schematic drawing showing a grouping of bonding pads with two rows of parallel-arranged bonding pads.

FIG. 7B is a schematic drawing showing a grouping of bonding pads with three rows of parallel-arranged bonding pads.

FIG. 8A is a 3D schematic drawing showing the a method of layout according to prior arts.

FIG. 8B is a 3D schematic drawing showing the a method of layout according to the present invention.

FIG. 9A shows the comparison of the frequency response of insertion loss of the high frequency between the convention package structure and the package structure of the present invention.

FIG. 9B shows the comparison of the frequency response of return loss of the high frequency between the conventional package structure and the package structure of the present invention.

FIG. 9C shows the comparison table of the insertion loss and return loss between those in the FIGS. 9A and 9B.

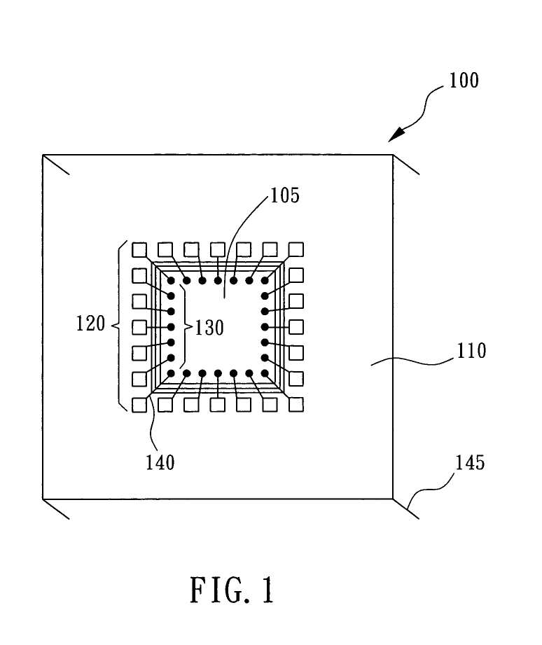

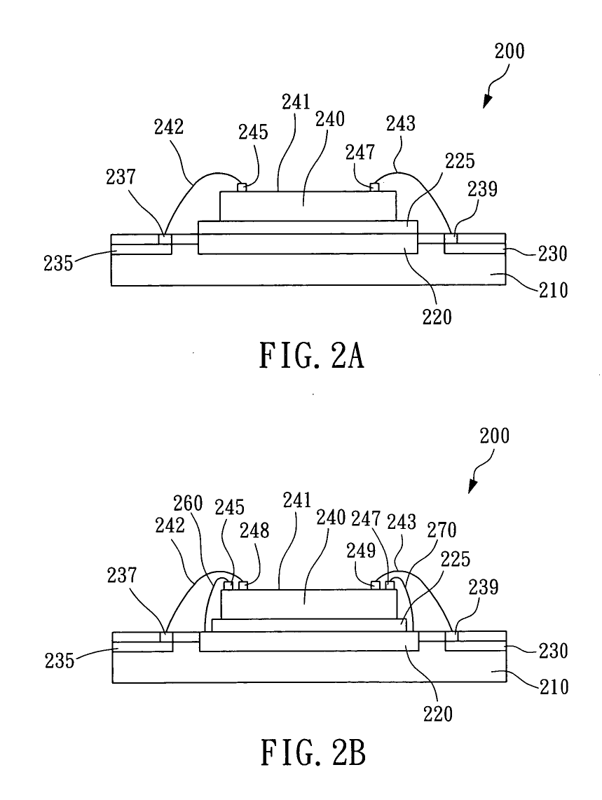

### DESCRIPTION OF THE PRESENT INVENTION

The objects, spirits and advantages of the preferred embodiments of the present invention will be readily understood by the accompanying drawings and detailed descriptions, wherein:

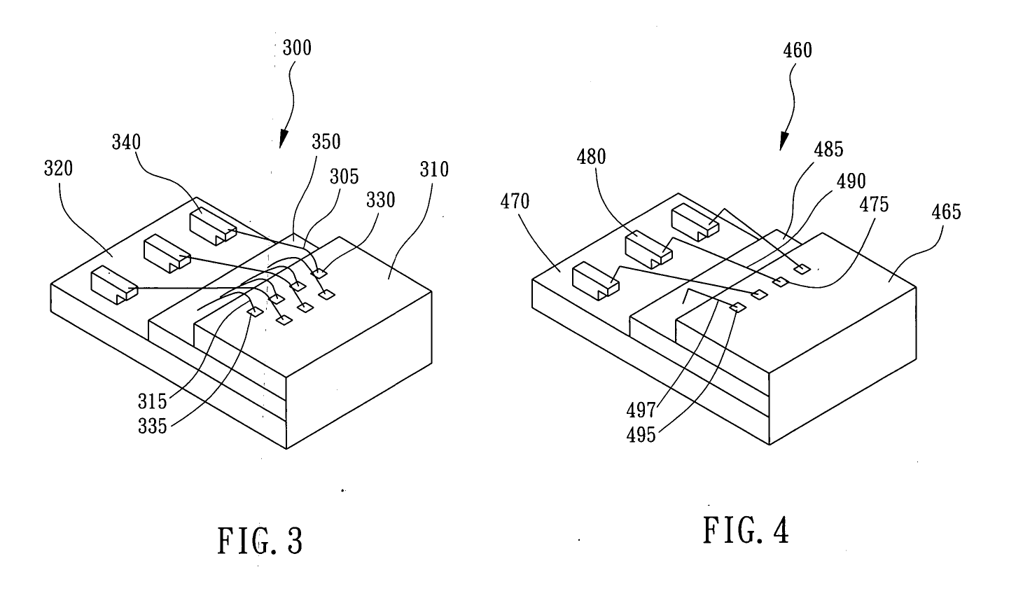

In general, the bonding of metal wires can be divided into normal and reverse bonding by the location of the initial point and the cutting point of a wire. Please refer to FIG. 3, which is a 3D schematic drawing showing a conventional package structure with normal bonding layout. In the package structure 300, the initial point of the metal wire 305 is first bonded on the bonding pad 330 of the chip 310, then forming an arc by upward-pulling the metal wires 305 having a cutting point connected to the pad 340 of the substrate 320; or the metal wires 315 is first bonded on the bonding pad 335 of the chip 310, then forming an arc by upward-pulling the metal wires 305 having a cutting point connected to the grounding plane 350 of the substrate 320. The aforementioned method of bonding is referred as normal bonding.

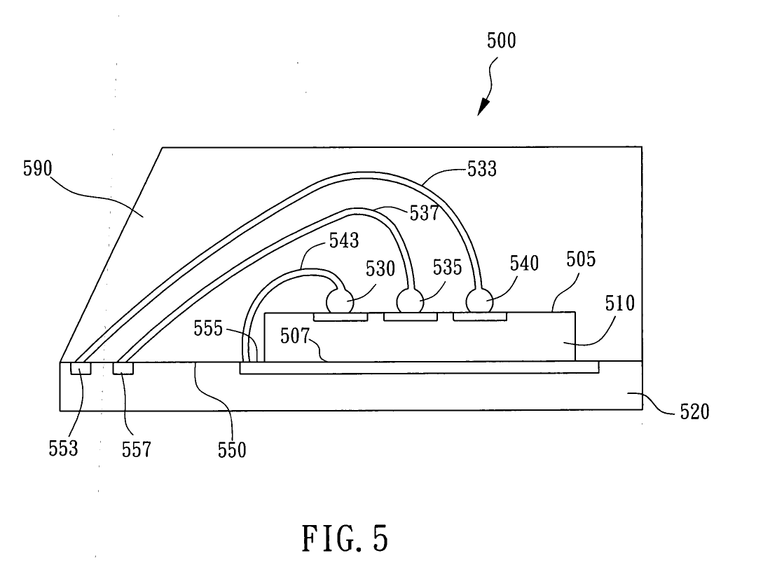

In contrary, package structure utilizing a reverse bonding method is shown on FIG. 4, which is a 3D schematic drawing showing a conventional package structure with reverse bonding layout In the package structure 460, the metal wire 490 is bonding on the pad 480 of the substrate 470 and ending at the bonding pad 475 of the chip 465, wherein the height of the arc of the metal wire 490 is lower but the radian of the metal wire 490 by the reverse bonding method is bigger than that of the metal wire 315 by the normal bonding method. Otherwise, the metal wire 497 is bonding on the grounding plane 485 of the substrate 470, forming an arc by upward-pulling of the metal wire 497 and ending on the grounding pad 495 of the chip. The aforementioned method of bonding is referred as reverse bonding.

In the normal bonding, because of the limitation of the arc height of the metal wires and the height of the QFN mold compound, employing the formation with three parallel row of bonding pads would be difficult. On the other hand, because the arc of the bonding wire in the reverse bonding has larger radian, the length of the bonding wires would be longer. Thus, the electrical characteristic of the package structure would be worse. In other words, the reverse bonding method is not suitable for a chip having multiple rows of bonding pads.

Because Radio-Frequency (RF) circuit or high-speed circuit has strict demands in efficiency and operating frequency, the present invention provides a structure of multi-tier wire bonding for high frequency integrated circuits and a method of layout for the same capable of using both normal bonding and reverse bonding simultaneously for enabling the electrical connection between the chip and the package to have best electrical characteristics.

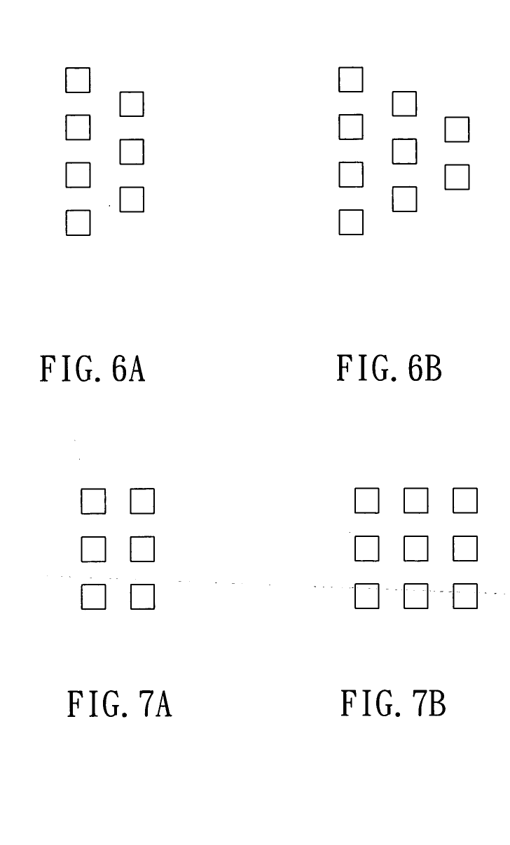

The present invention provides a structure of multi-tier wire bonding for high frequency integrated circuits and a method of layout for the same capable of using both normal bonding and reverse bonding simultaneously. Please refer to FIG. 5, which is a schematic drawing showing an embodiment of a package structure with multiple rows of bonding pads. The package structure 500 having multiple rows of bonding pads comprises a first electronic device 510 and a second electronic device 520. The first electronic device 510 and the second electronic device 520 can be a chip and a substrate respectively. The chip 510 comprises a bonding surface 505 and a carrying surface 507 arranged opposite to the bonding surface 505. A grouping of bonding pads which can be divided into at least two rows, i.e. the first row and the second row, etc., are distributed at the border of the bonding surface 505. Wherein, the first row is away from the center of the bonding surface 505 whereas the second row is close to the center of the bonding surface 505, and so on. In the present embodiment, there are the first row bonding pads 530, the second row bonding pads 535, and the third row bonding pads 540 on the bonding surface 505. The substrate 520 has a carrying surface 550 abutted upon the carrying surface 507 of the chip 510.

Furthermore, a grouping of bonding pads is located at the border of the carrying surface 550 and can be divided into multiple rows. In the present embodiment, there are two rows of bonding pads 553, 557 on the carrying surface 550. In carrying surface 550, there are also linear bonding pads 555 surround the chip 510 like a ring.

The layout of metal wires is as following: first, connecting a metal wire starting from one bonding pad of the grouping of bonding pads of the substrate 520 to one of the first row bonding pads of the chip 510 using reverse bonding, thereafter, connecting another metal wire starting from one bonding pad of the grouping of bonding pads of the chip 510 to one of the bonding pads of the substrate 520 using normal bonding. In the present embodiment, the metal wire 543 is reverse bonding starting from the linear bonding pad 555 and ending at one of the first row bonding pad 530. The metal wire 537 is normal bonding starting from one of the second row bonding pad 535 and ending at one of the fifth row bonding pad 557. The metal wire 533 is normal bonding starting from one of the third row bonding pad 540 and ending at one of the forth row bonding pad 553.

After finishing the bonding of the metal wires 543, 537, 533 connecting between the chip 510 and the substrate 520, a layer of epoxy 590 is covered thereon such that the structure 500 is accomplished.

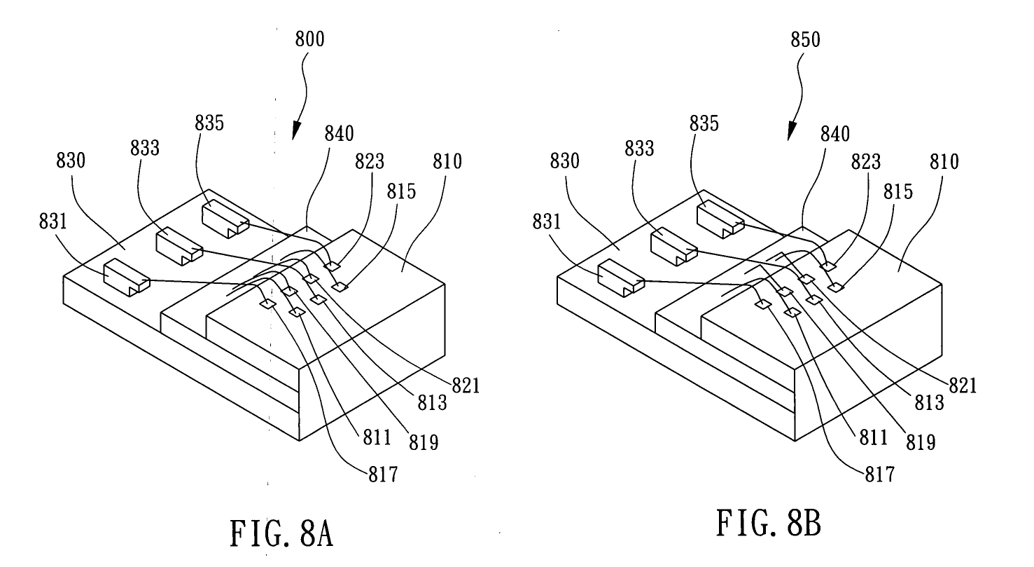

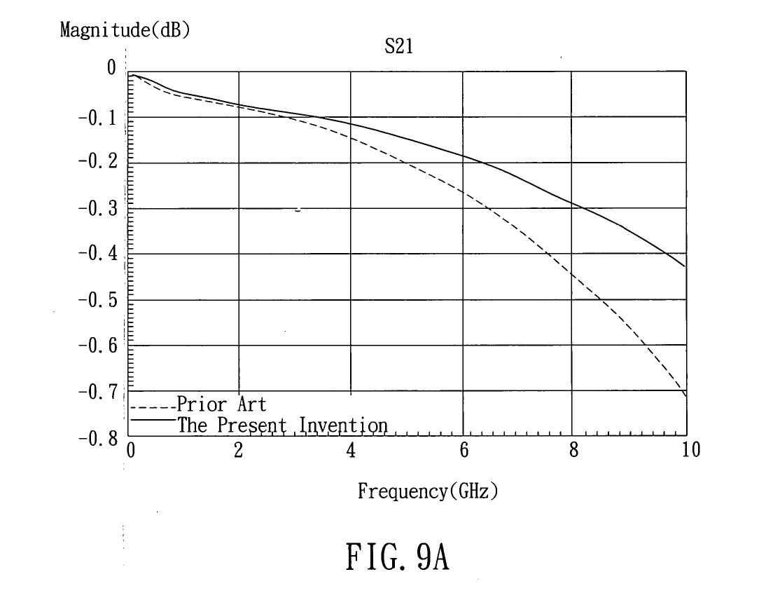

In the preferred embodiment, since the reverse bonding is being used for connecting the chip 510 and the first row bonding pad 530, thus, the arc height of the metal wire 543 at the first row bonding pad 530 is almost the same as that at the first row bonding pad 530. Thus, the arc height of the metal wire 537 at the second row bonding pad 535 on the chip 510 can remain without change The arc height of the metal 533 at the third row bonding pad 540 only needs to be raised a little higher than that of the metal wire 537. Therefore, the layout of the present invention can not only be applied to two rows of parallel-arranged or interlace-arranged bonding pads, but also be applied to three rows of parallel-arranged or interlace-arranged bonding pads. Please refer to the FIGS. 6A, 6B, 7A, and 7B. FIGS. 6A and 6B are the diagrams of two rows and three rows of interlace-arranged bonding pads, in respectively. FIGS. 7A and 7B are the diagrams of two rows and three rows of parallel-arranged bonding pads, in respectively.

In additions, in the preferred embodiment with reference to FIG. 5, the high frequency signal can be transferred between the chip 510 and the substrate 520 through the metal wires 537, 533. The grounding line can be connected to the linear bonding pad 555 of the substrate 520 through the metal wire 543. Therefore, to complete a transferring of high frequency signal, a grounding protection circuit constructed using reverse bonding so as to possesses characteristic of low arc height at the position near the chip and short grounding distance is arranging on each sides of the metal wire transferring the high frequency signal

Thus, the present invention lowers the height of arc of metal wires, and also lowers the insertion loss and the return loss by the reverse bonding method such that the electrical characteristics between the electronic devices are improved.

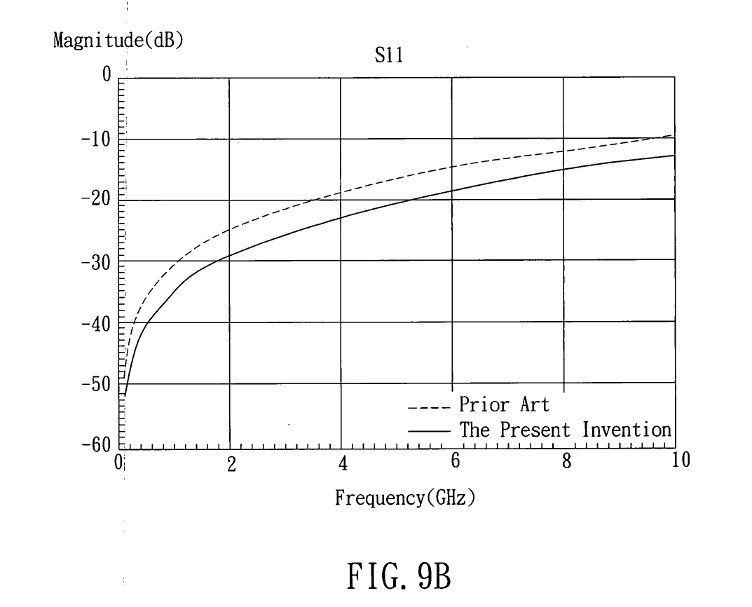

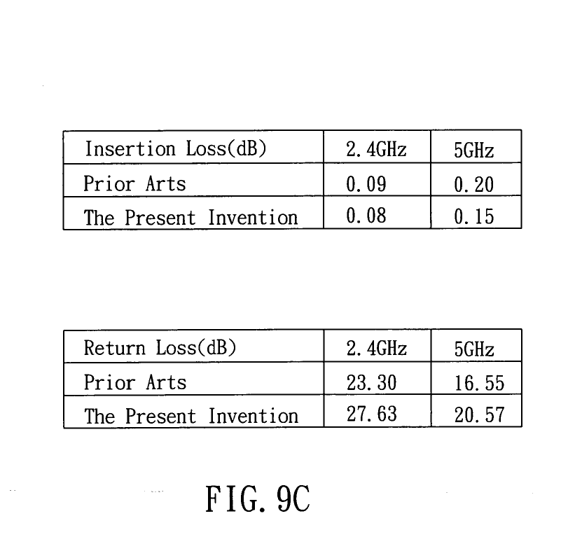

The layout of the present invention is compared with the conventional bonding method on the package structure having the same electronic devices. Please refer to FIGS. 8A and 8B, which show 3D drawings of the bonding methods of the conventional method and an embodiment of the present invention, in respectively. In FIG. 8A, the structure 800 comprises a chip 810, and a substrate 830. There are two rows of bonding pads on the chip 810. The first row comprises bonding pads 817, 819, 821, 823 whereas the second row comprises bonding pads 811, 813, 815. The substrate 830 comprises a row of bonding pads 831, 833, 835 and the linear bonding pad 840. Only the bonding pad 813 of the chip 810 and the bonding pad 833 of the substrate 830 are used for signal transferring, the other bonding pads are used for grounding. The connections among bonding pads are by the following methods: The metal wires are normal bonding starting from the bonding pads of the chip 810 and ending at the bonding pads of the substrate 830. The grounded wires are on each sides of the signal wire at the bonding pad 813, and are grounding by a normal bonding method. In FIG. 8B which is using the same package structure as in FIG. 8A, the grounded wires are grounded by a reverse bonding method. In other words, the metal wires are reverse bonding starting from the linear bonding pad 840 of the substrate 830 and ending at the bonding pads 819 and 821 of the chip 810. The insertion loss and the return loss of the structure 800 will be reduced if uses the bonding method of FIG. 8B in compared to that in FIG. 8A. The experimental data of the insertion loss and the return loss of the structure 800 are shown in FIGS. 9A, 9B and 9C. FIG. 9A shows the frequency response of the insertion loss of high frequency in the conventional method and in the embodiment of the present invention. FIG. 9B shows the frequency response of the return loss of high frequency in the conventional method and in the embodiment of the present invention. The table in FIG. 9C shows the comparison of the frequency of the insertion loss and the return loss between that in the conventional method in FIG. 9A and in the embodiment in FIG. 9B.

In summary, the present invention provides a structure of multi-tier wire bonding for high frequency integrated circuits and a method of layout for the same capable of using both normal bonding and reverse bonding simultaneously for enabling the electrical connection between the chip and the package to have best electrical characteristics. By reverse bonding, the arc height of the metal wires can be reduced such that three rows of parallel-arranged bonding pads can be achieved in a package structure without affecting the height of the mold compound. Furthermore, by the reverse bonding method, the insertion loss and the return loss of high frequency can be reduced and increased, respectively. Therefore, the high frequency signal can be fully conducted and the impedance mismatch will be reduced. The electrical characteristics of the structure are improved.

While the present invention has been shown and described with reference to preferred embodiments thereof, and in terms of the illustrative drawings, it should be not considered as limited thereby. Various possible modification, omission, and alterations could be conceived of by one skilled in the art to the form and the content of any particular embodiment, without departing from the scope and the spirit of the present invention.

What is claimed is:

1. A structure of multi-tier wire bonding for high frequency integrated circuits, comprising:
a plurality of interlace-arranged bonding pads located on a chip;
a plurality of pads located on a substrate, wherein a pad located on the substrate for transferring a high frequency signal is surrounded by two grounded pads located on the substrate; and
at least one grounding surface;
wherein a bonding pad on the chip for transferring high frequency signals is connected to the pad on the substrate for transferring high frequency signals using normal bonding, and the two grounded pads surrounding the pad on the substrate for transferring high frequency signals are connected respectively from the grounding surface to the chip using reverse bonding.

2. The structure according to claim 1, wherein the plural bonding pads located on the chip can be divided into a first row bonding pads which is away from a center of the chip and a second row bonding pads which is close to the center of the chip.

3. The structure according to claim 1, wherein the plural pads on the substrate can be divided into at least a first row pads which is away from a center of the substrate and a second row pads which is close to the center of the substrate.

4. The structure according to claim 3, wherein the bonding pad on the chip for transferring high frequency signals is one of the second row bonding pads on the chip.

5. The structure according to claim 4, wherein the two grounded pads surrounding the pad on the substrate for transferring high frequency signals are connected respectively from the grounding surface to the prescribed first row bonding pads on the chip using reverse bonding.

6. The structure according to claim 2, wherein the chip comprises a third row bonding pads.

7. A structure of multi-tier wire bonding for high frequency integrated circuits, comprising:
a plurality of interlace-arranged bonding pads located on a chip;
a plurality of pads located on a substrate, wherein a pad located on the substrate for transferring a high frequency signal is surrounded by two grounded pads located on the substrate; and
at least one grounding surface;
wherein an arc height of a metal wire for transferring the high frequency signal is higher than that of surrounding metal wires for grounding.

8. The structure according to claim 7, wherein the plural bonding pads located on the chip can be divided into a first row bonding pads which is away from a center of the chip and a second row bonding pads which is close to the center of the chip.

9. The structure according to claim 7, wherein the plural pads on the substrate can be divided into at least a first row pads which is away from a center of the substrate and a second row pads which is close to the center of the substrate.

10. The multi-wire package structure according to claim 8, wherein the bonding pad on the chip for transferring high frequency signals is one of the second row bonding pads on the chip.

11. The structure according to claim 10, wherein the bonding pad on the chip for transferring high frequency signals is connected to the pad on the substrate for transferring high frequency signals using normal bonding, and the two grounded pads surrounding the pad on the substrate for transferring high frequency signals are connected respectively from the grounding surface to the chip using reverse bonding.

12. The structure according to claim 11, wherein the two grounded pads surrounding the pad on the substrate for transferring high frequency signals are connected respectively from the grounding surface to the prescribed first row bonding pads on the chip using reverse bonding.

13. The multi-wire package structure according to claim 7, the chip comprises a third row bonding pads.

14. A structure of multi-tier wire bonding for high frequency integrated circuits, comprising:
a first electronic device, further comprising:
a first bonding surface;
a first carrying surface arranged on a side of the first electronic device opposite to the first bonding surface; and
a first grouping of bonding pads, distributed surrounding the border of the first bonding surface, being divided into the first row and the second row bonding pads, the first row of bonding pads is away from whereas the second row bonding pads are close to the center of the first bonding surface; and
a second electronic device, further comprising:
a second carrying surface, abutted against the first carrying surface for carrying the first electronic device, such that the first electronic device and the second electronic device overlap one another;
a second grouping of bonding pads, located on the second carrying surface is distributed surrounding the border thereof; and
a plurality of metal wires for electronically connecting the first electronic device with the second electronic device, the plural metal wires employing both a method of normal bonding and a method of reverse bonding for connecting, and both methods defining an initial point and a cutting point for the bonded wire;
wherein, the initial point of a wire of normal bonding is connected to a bonding pad of the first grouping, and the cutting point of a wire of normal bonding is connected to a bonding pad of the second grouping, on the other hand, the connection for the wires of reverse bonding is the opposite to that of the wires of normal bonding.

15. The structure according to claim 14, wherein said first grouping of bonding pads further comprises a third row bonding pads.

16. The structure according to claim 14, wherein the second grouping of bonding pads comprise a fourth row bonding pads located away from the center of the second carrying surface and a fifth row bonding pads located close to the center of the second carrying surface.

17. The structure according to claim 15, wherein the initial points of the metal wires employing normal bonding are connected to one bonding pad of the third row bonding pads, and the cutting points of the metal wires employing normal bonding are connected to one bonding pad of the second grouping of bonding pads.

18. The structure according to claim 14, wherein the second grouping of bonding pads further comprise a sub-grouping of bonding pads, and the sub-grouping of bonding pads surrounds the first carrying surface linearly.

19. The structure according to claim 18, wherein the sub-grouping of bonding pads is grounded.

20. The structure according to claim 19, wherein the initial point of one of the metal wires employing reverse bonding is connected to the sub-grouping of bonding pads, and the cutting points of the metal wires employing reverse bonding is connected to one bonding pad of the first row bonding pads.

21. The structure according to claim 14, wherein the first row bonding pads and the second row bonding pads are interleave arranged.

22. The structure according to claim 14, wherein said first row bonding pads and the second row bonding pads are arranged in parallel.

23. The structure according to claim 14, wherein the first electronic device is one of the following: a chip and a substrate.

24. The structure according to claim 14 wherein the second electronic device is one of the following: a chip and a substrate.

25. A method of multi-tier wire bonding for high frequency integrated circuits, adapted for connecting a first electronic device with a second electronic device in a multi-tier package structure, wherein, the first electronic device overlaps with the second electronic device, the first electronic device has a first bonding surface arranged thereon a first grouping of bonding pads which can be divided into at least a first row bonding pads and a second row bonding pads arranged from the edge of the first bonding surface to the center thereof, and the second electronic device has a second bonding surface arranged thereon a second grouping of bonding pads which is distributed at the edge of the surface abutted against the first electronic device, the method comprising:
using reverse bonding to bond a metal wire out of a plurality of metal wires starting from a bonding pad out of the second grouping of bonding pads and ending at a bonding pad out of the first row bonding pads;
using normal bonding to bond a metal wire out of the plural metal wires starting from a bonding pad out of the first grouping of bonding pads and ending at a bonding pad out of the second grouping of bonding pads.

26. The method according to claim 25, wherein the first bonding pads comprises a third row bonding pads.

27. The method according to claim 25, wherein the second grouping of bonding pads comprise a fourth row bonding pads located away from the center of the second carrying surface and a fifth row bonding pads located close to the center of the second carrying surface.

28. The method according to claim 26, wherein the method further comprise:
using normal bonding to bond a metal wire out of the plural metal wires starting from a bonding pad out of the third row bonding pads and ending at a bonding pad out of the second grouping of bonding pads.

29. The method according to claim 25, wherein the second grouping of bonding pads further comprise a sub-grouping of bonding pads, and the sub-grouping of bonding pads surrounds the first carrying surface linearly.

30. The method according to claim 29, wherein the sub-grouping of bonding pads is grounded.

31. The method according to claim 30, wherein the initial point of one of the metal wires employing reverse bonding is connected to the sub-grouping of bonding pads, and the cutting points of the metal wires employing reverse bonding is connected to one bonding pad of the first row bonding pads.
